(19) United States
(12) Patent Application Publication
(10) Pub. No.: US 2017/0127535 A1
(43) Pub. Date: May 4, 2017

(54) SYSTEM AND METHOD FOR CONTROLLING CURVATURE OF VIEWER ADAPTIVE TYPE FLEXIBLE DISPLAY IN ORDER TO INCREASE IMMERSIVE FEELING

(71) Applicant: INDUSTRIAL BANK OF KOREA, Seoul (KR)

(72) Inventors: Pilsoon SHIN, Busan (KR); Jongman KWON, Gwangju-si (KR)

(21) Appl. No.: 14/926,774

(22) Filed: Oct. 29, 2015

(51) Int. Cl. H05K 5/00; H05K 5/02

(52) U.S. Cl. CPC H05K 5/0017; H05K 5/0217

(57) ABSTRACT

The present invention provides a system and method for controlling a curvature of a viewer adaptive type flexible display in order to increase an immersive feeling. According to the system and method for controlling a curvature of a viewer adaptive type flexible display in order to increase an immersive feeling, a user may directly control a curvature of a flexible display so that the curvature of the flexible display may be changed according to a separation distance of a viewer positioned in front of the flexible display and the number of viewers, or the separation distance of the viewer positioned in front of the flexible display and the number of viewers may be detected in real time so that the curvature of the flexible display may be changed in real time to have an optimal curvature value corresponding to the separation distance of the viewer and the number of viewers.

### BACKGROUND

1. Field of the Invention

The present invention relates to a system and method for controlling a curvature of a viewer adaptive type flexible display in order to increase an immersive feeling, and more particularly, to a system and method for controlling a curvature of a viewer adaptive type flexible display in order to increase an immersive feeling, in which a user may directly control a curvature of a flexible display so that the curvature of the flexible display may be changed according to a separation distance of a viewer positioned in front of the flexible display and the number of viewers, or the separation distance of the viewer positioned in front of the flexible display and the number of viewers may be detected in real time so that the curvature of the flexible display may be changed in real time to have an optimal curvature value corresponding to the separation distance of the viewer and the number of viewers, and therefore it is possible to provide an optimal display environment that can be adapted to various viewing conditions, and thereby maximize an immersive feeling of the viewer.

2. Discussion of Related Art

A flexible display is a flat panel display that is formed on a flexible substrate such as plastic, and can be transformed into a roll form in such a manner as to be bent or folded while having excellent display characteristics as is, and thereby worldwide interest in the flexible display is growing as the next generation technology in the current flat panel display market. Such a flexible display may be classified into a rugged display, a bending display, and a rollable display according to applications and functions thereof. The flexible display that is lightweight, robust, and bendable may be applied to smart phones, smart pads, and the like so the commercial development is in progress, and technology development in which the flexible display is applied to a variety of display devices such as TV monitors, computer monitors, screens, and the like is actively progressing.

As the flexible display-related technologies, the Republic of Korea Patent Application No. 10-1278451 entitled “flexible screen for displaying contents and diary type information providing apparatus including flexible terminal for controlling the same” and the Republic of Korea Patent Application Laid-Open No. 10-2013-0021566 entitled “manufacturing method for flexible display device and flexible display device” are disclosed.

Meanwhile, a curvature radius of the flexible display that is currently commercialized is fixed, so there is a limitation to provide an optimal display environment that is appropriately adaptive to various viewing conditions of viewers using the flexible display, and there is also a limitation to increase an immersive feeling of the viewer through the flexible display.

### PRIOR ART DOCUMENTS

(Patent Document 1) The Republic of Korea Patent Application No. 10-1278451 entitled “Flexible screen for displaying contents and diary type information providing apparatus including flexible terminal for controlling the same”

(Patent Document 2) The Republic of Korea Patent Application Laid-Open No. 10-2013-0021566 entitled “Manufacturing method for flexible display device and flexible display device”

### SUMMARY OF THE INVENTION

The present invention is directed to a system and method for controlling a curvature of a viewer adaptive type flexible display in order to increase an immersive feeling of the viewer, in which a user may directly control a curvature of a flexible display so that the curvature of the flexible display may be changed according to a separation distance of a viewer positioned in front of the flexible display and the number of viewers, or the separation distance of the viewer positioned in front of the flexible display and the number of viewers may be detected in real time through a viewer separation distance detector or a viewer number detector, an optimal curvature value corresponding to the separation distance of the viewer or the number of viewers may be calculated in real time by a display curvature control device including an optimal curvature calculation algorithm, and the curvature of the flexible display may be changed in real time to have an optimal curvature value by a curvature change device, and therefore it is possible to provide an optimal display environment that can be adapted to various viewing conditions, and thereby maximize an immersive feeling of the viewer.

According to an aspect of the present invention, there is provided a system for controlling a curvature of a viewer adaptive type flexible display in order to increase an immersive feeling, including: a flexible display that is made of a bendable flexible material whose curvature can be changed; and a curvature change device that is installed in the flexible display and changes a current curvature of the flexible display, wherein the curvature change device is controlled by any one selected from direct control by a user and automatic control by a display curvature control device.

Here, the system may further include a viewer information detection device that detects viewer information of a viewer positioned in front of the flexible display, wherein the display curvature control device includes an optimal curvature calculation algorithm that receives the viewer information from the viewer information detection device and calculates an optimal curvature of the flexible display corresponding to the viewer information, and thereby generates optimal curvature value information corresponding to current viewer information and transmits the generated optimal curvature value information to the curvature change device.

Also, the viewer information detection device may be any one selected from a viewer separation distance detector for detecting a separation distance between a viewer positioned in front of the flexible display and the flexible display and a viewer number detector for detecting the number of viewers positioned in front of the flexible display, and an optimal curvature calculation algorithm of the display curvature control device may include a separation distance adaptive type optimal curvature calculation algorithm for calculating an optimal curvature of the flexible display corresponding to the separation distance of the viewer, a viewer number adaptive type optimal curvature calculation algorithm for calculating the optimal curvature of the flexible display corresponding to the number of viewers, and a complex viewer information adaptive type optimal curvature calculation algorithm for calculating the optimal curvature of the flexible display corresponding to the separation distance of the viewer and the number of viewers.

Also, the curvature change device may be any one selected from an external curvature change device that includes a fixed block to which the flexible display is fixed and an actuator for the fixed block that changes a current curvature of the flexible display by moving the fixed block, and an internal curvature change device that is disposed inside the flexible display to directly change a current curvature of a main substrate constituting the flexible display.

Also, the system may further include a viewer position detection device that detects a position of a viewer positioned in front of the flexible display; a display rotation control device that includes a panning angle calculation algorithm for receiving a viewer position value from the viewer position detection device and calculating a panning angle of the flexible display corresponding to the viewer position value, and thereby generates a panning angle corresponding to a current viewer position; and a display rotation device to which the flexible display is coupled, and that receives the panning angle from the display rotation control device and rotates the flexible display using the received panning angle.

Also, the system may further include a viewer position detection device that detects a position of a viewer positioned in front of the flexible display; a display tilting control device that includes a tilting angle calculation algorithm for receiving a viewer position value from the viewer position detection device and calculating a tilting angle of the flexible display corresponding to the viewer position value, and thereby generates a tilting angle corresponding to a current viewer position; and a display tilting device to which the flexible display is coupled, and that receives the tilting angle from the display tilting control device and rotates the flexible display using the received tilting angle.

According to another aspect of the present invention, there is provided a method for controlling a curvature of a viewer adaptive type flexible display in order to increase an immersive feeling, including: detecting, by a viewer information detection device, viewer information of a viewer positioned in front of a flexible display that is made of a bendable flexible material whose curvature can be changed; calculating, by an optimal curvature calculation algorithm provided in a display curvature control device that receives the viewer information from the viewer information detection device, an optimal curvature value of the flexible display corresponding to current viewer information; and changing, by a curvature change device that receives the optimal curvature value transmitted from the display curvature control device, a current curvature of the flexible display.

Here, the detecting of the viewer information may include detecting any one selected from a separation distance between the viewer positioned in front of the flexible display and the flexible display and the number of viewers positioned in front of the flexible display, as the viewer information, and the calculating of the optimal curvature value may include calculating any one selected from the optimal curvature value of the flexible display corresponding to the separation distance of the viewer, the optimal curvature value of the flexible display corresponding to the number of viewers, and the optimal curvature value of the flexible display corresponding to the separation distance of the viewer and the number of viewers.

Also, the calculating of the optimal curvature value may include calculating the optimal curvature value in such a manner that a curvature radius of the flexible display is increased along with an increase in the separation distance of the viewer, and calculating the optimal curvature value in such a manner that the curvature radius of the flexible display is increased along with an increase in the number of viewers.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is an example of a flexible display;

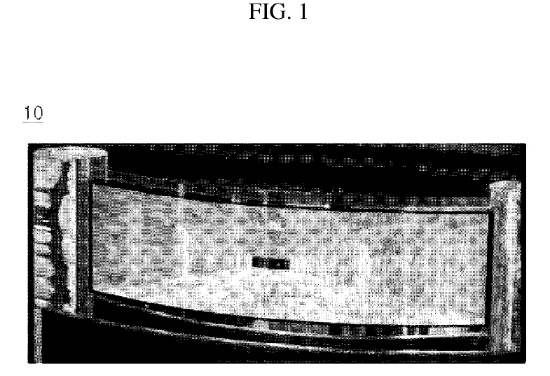

FIGS. 2(a) and 2(b) are basic configuration diagrams of a system for controlling a curvature of a viewer adaptive type flexible display in order to increase an immersive feeling according to an embodiment of the present invention;

FIG. 3 is a block diagram of a configuration of a display curvature control device according to an embodiment of the present invention;

FIGS. 4(a) and 4(b) are examples of a configuration of a curvature change device according to an embodiment of the present invention;

FIGS. 5(a) and 5(b) are basic configuration diagrams of a system for controlling a curvature of a viewer adaptive type flexible display in order to increase an immersive feeling according to an embodiment of the present invention;

FIGS. 6(a) and 6(b) are views showing a rotation pattern of a flexible display according to a user position;

FIG. 7 is a block diagram showing a method for controlling a curvature of a viewer adaptive type flexible display in order to increase an immersive feeling according to an embodiment of the present invention;

FIGS. 8(a) and 8(b) are views showing a curvature radius change pattern of a flexible display according to a user separation distance; and

FIGS. 9(a) and 9(b) are views showing a curvature radius change pattern of a flexible display according to the number of users.

### DETAILED DESCRIPTION OF EXEMPLARY EMBODIMENTS

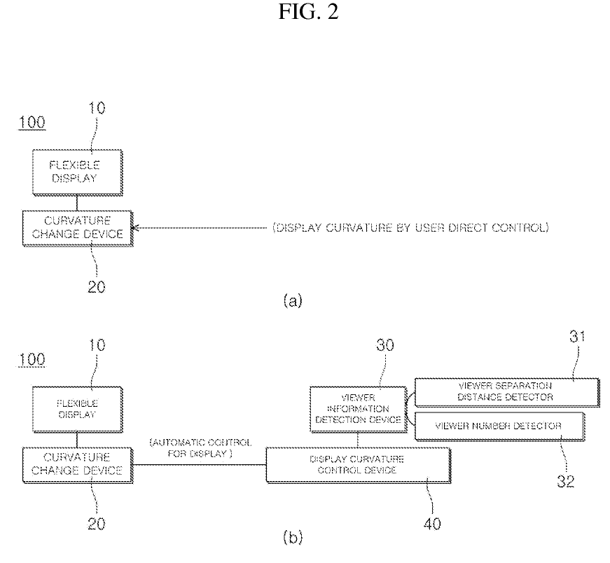

Hereinafter, preferred embodiments according to the present invention will be described with reference to FIGS. 2 to 9. Meanwhile, in the drawings and detailed description, illustration and description of the configuration and operation which can be easily known by those skilled persons in the related art from a general flexible display, a technique for detecting a distance of an object, a technique for identifying an object, and the like will be simplified or omitted. In particular, in the illustration of the drawings and detailed descriptions, detailed description and illustration of specific technical configurations and operations of elements which are not associated directly with the technical features of the present invention will be omitted, and only technical configuration which is associated with the present invention will be simply illustrated or described.

A system 100 for controlling a curvature of a viewer adaptive type flexible display in order to increase an immersive feeling according to an embodiment of the present invention includes a flexible display 10 and a curvature change device 20 as shown in FIGS. 2(a) and 2(b).

The flexible display 10 is a display device that is made of a flexible material whose curvature can be changed. Here, the system 100 for controlling a curvature of a viewer adaptive type flexible display in order to increase an immersive feeling according to an embodiment of the present invention may be effectively applied to a flexible display used as a TV monitor or a PC monitor having a medium/large screen of a predetermined size or more, and thereby may maximize the immersive feeling of a viewer. Obviously, the system 100 for controlling a curvature of a viewer adaptive type flexible display in order to increase an immersive feeling according to an embodiment of the present invention may be applied to a screen in which an image output from a projector is displayed.

The curvature change device 20 is a device that is installed in the flexible display 10 to change a current curvature of the flexible display 10.

Here, the curvature change device 20 may change the current curvature of the flexible display 10 while being controlled directly by a user as shown in FIG. 2(a), or change the current curvature of the flexible display 10 while being automatically controlled by a display curvature control device 40 as shown in FIG. 2(b).

For this, the system 100 for controlling a curvature of a viewer adaptive type flexible display in order to increase an immersive feeling according to an embodiment of the present invention may include a viewer information detection device 30 and the display curvature control device 40.

The viewer information detection device 30 detects viewer information about a viewer positioned in front of the flexible display 10. The viewer information may include a viewer separation distance from the flexible display 10 and the number of viewers positioned in front of the flexible display 10. Here, any one selected from the viewer separation distance and the number of viewers may be detected, or both the viewer separation distance and the number of viewers may be detected. Such a viewer information detection device 30 may detect the viewer separation distance and the number of viewers through image photographing, include a separate sensor (an ultrasonic sensor, an infrared sensor, an optical sensor, or the like) for detecting the viewer separation distance or the number of viewers, or detect the viewer separation distance or the number of viewers while detecting an electronic tag which a viewer possesses.

Such a viewer information detection device 30 may include a viewer separation distance detector 31 and a viewer number detector 32, and the viewer separation distance detector 31 is a device that detects a separation distance between the viewer positioned in front of the flexible display 10 and the flexible display 10. Such a viewer separation distance detector 31 may be constituted of an electronic tag mounted in a remote control and a tag detection module for RTLS mounted in the flexible display 10, constituted of an image photographing device, or constituted of a sensor for detecting an object such as an ultrasonic sensor, an infrared sensor, an optical sensor, or the like.

The viewer number detector 32 is a device that detects the number of viewers positioned in front of the flexible display 10. Such a viewer number detector 32 may be constituted of an electronic tag mounted in a remote control and a tag detection module for RTLS mounted in the flexible display 10, constituted of an image photographing device, or constituted of a sensor for detecting an object such as an ultrasonic sensor, an infrared sensor, an optical sensor, or the like.

Any one selected from the viewer separation distance detector 31 and the viewer number detector 32 may be provided, or both the viewer separation distance detector 31 and the viewer number detector 32 may be provided.

The display curvature control device 40 is a device that receives the viewer information from the viewer information detection device 30 and calculates an optical curvature of the flexible display 10. For this, the display curvature control device 40 includes an optimal curvature calculation algorithm 41 that calculates the optimal curvature of the flexible display 10 corresponding to the viewer information. Such an optimal curvature calculation algorithm 41 generates an optimal curvature value corresponding to current viewer information, and the display curvature control device 40 transmits the generated optimal curvature value to the curvature change device 20.

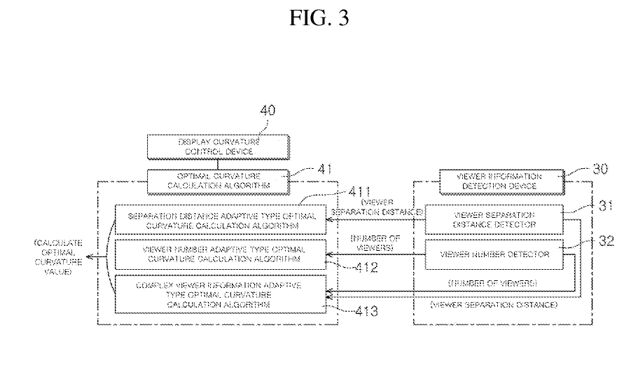

Here, the optimal curvature calculation algorithm 41 of the display curvature control device 40 may include a separation distance adaptive type optimal curvature calculation algorithm 411 that calculates the optimal curvature of the flexible display 10 corresponding to the viewer separation distance, a viewer number adaptive type optimal curvature calculation algorithm 412 that calculates the optimal curvature of the flexible display 10 corresponding to the number of viewers, and a complex viewer information adaptive type optimal curvature calculation algorithm 413 that calculates the optimal curvature of the flexible display 10 corresponding to the separation distance of the viewer and the number of viewers, as shown in FIG. 3. The separation distance adaptive type optimal curvature calculation algorithm 411 is activated when only the viewer separation distance is detected, the viewer number adaptive type optimal curvature calculation algorithm 412 is activated when only the number of viewers is detected, and the complex viewer information adaptive type optimal curvature calculation algorithm 413 is activated when both the viewer separation distance and the number of viewers are detected.

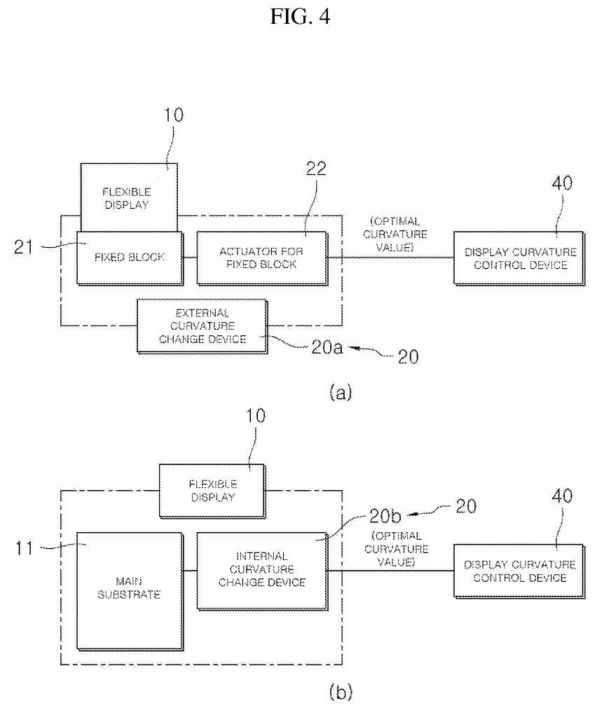

The curvature change device 20 may be constituted of an external curvature change device 20a or an internal curvature change device 20b, as shown in FIGS. 4(a) and 4(b). The external curvature change device 20a may include a fixed block 21 to which the flexible display 10 is fixed and an actuator 22 for the fixed block that changes a current curvature of the flexible display 10 by moving the fixed block 21. Moreover, a display curvature control device 40 can control an optimal curvature value for the actuator 22 for the fixed block, as illustrated in FIG. 4(a).

The internal curvature change device 20b is a device that is disposed inside the flexible display 10 to directly change a current curvature of a main substrate 11 constituting the flexible display 10. Similar to external curvature change device 20a, the display curvature control device 40 can control an optimal curvature value for the internal curvature change device 20b, as illustrated in FIG. 4(b).

Meanwhile, the system 100 for controlling a curvature of a viewer adaptive type flexible display in order to increase an immersive feeling according to an embodiment of the present invention may enable screen brightness of the flexible display 10 to be automatically adjusted according to the viewer separation distance. That is, as the viewer separation distance becomes smaller, the screen brightness of the flexible display 10 may automatically become dark. For this, a screen brightness automatic adjusting device may be additionally provided.

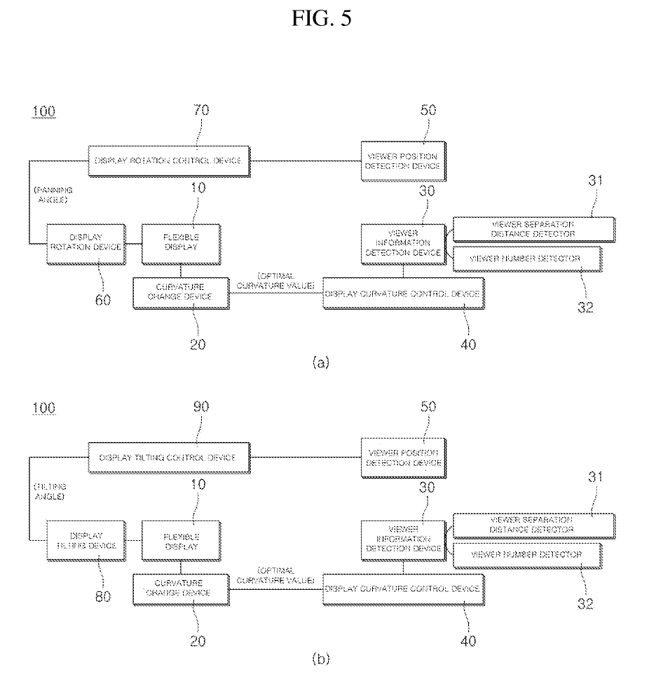

The system 100 for controlling a curvature of a viewer adaptive type flexible display in order to increase an immersive feeling according to another embodiment of the present invention may further include a viewer position detection device 50, a display rotation control device 70, and a display rotation device 60 as shown in FIG. 5(a), or further include a display tilting control device 90 and a display tilting device 80 as shown in FIG. 5(b). It is preferable that the display rotation control device 70, the display rotation device, the display tilting control device 90, and the display tilting device 80 be simultaneously provided, but only the display rotation control device 70 and the display rotation device 60 may be provided, or only the display tilting control device 90 and the display tilting device 80 may be provided.

The viewer position detection device 50 is a device that detects a position of a viewer positioned in front of the flexible display 10. Such a viewer position detection device 50 may be constituted of an electronic tag mounted in a remote control and a tag detection module for RTLS mounted in the flexible display 10, constituted of an image photographing device, or constituted of a sensor for detecting an object such as an ultrasonic sensor, an infrared sensor, an optical sensor, or the like.

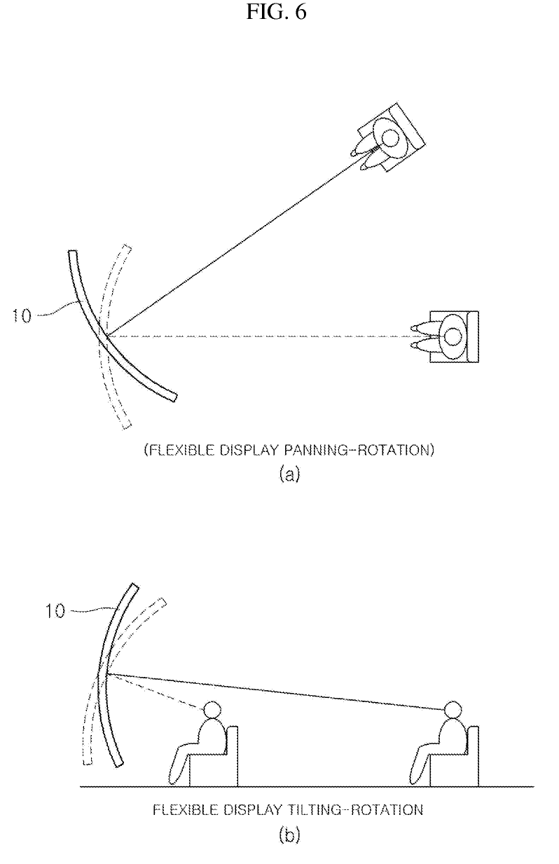

The display rotation control device 70 is a device that includes a panning angle calculation algorithm for receiving a viewer position value from the viewer position detection device 50 and calculating a panning angle of the flexible display 10 corresponding to the viewer position value to thereby generate a panning angle corresponding to a current viewer position. The display rotation device 60 to which the flexible display 10 is coupled receives the panning angle from the display rotation control device 70, and panning-rotates the flexible display 10 using the received panning angle as shown in FIG. 6(a).

The display tilting control device 90 is a device that includes a tilting angle calculation algorithm for receiving a viewer position value from the viewer position detection device 50 and calculating a tilting angle of the flexible display 10 corresponding to the viewer position value, and thereby generates a tilting angle corresponding to a current viewer position. The display tilting device 80 to which the flexible display 10 is coupled receives the tilting angle from the display tilting control device 90, and tilting-rotates the flexible display 10 using the received tilting angle as shown in FIG. 6(b).

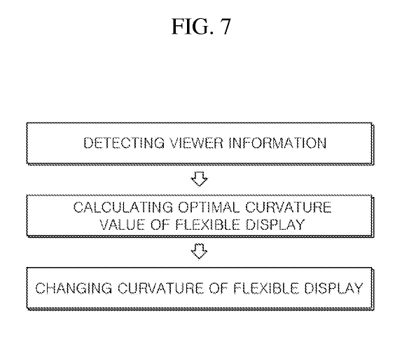

A method for controlling a curvature of a viewer adaptive type flexible display in order to increase an immersive feeling according to an embodiment of the present invention includes detecting a viewer information, calculating a flexible display optimal curvature value, and changing a flexible display curvature as shown in FIG. 7.

In the detecting of the viewer information, viewer information about a viewer positioned in front of the flexible display 10 made of a bendable flexible material whose curvature can be changed is detected by the viewer information detection device 30. The viewer information may include a viewer separation distance from the flexible display 10 and the number of viewers positioned in front of the flexible display 10. Here, any one selected from the viewer separation distance and the number of viewers may be detected or both the viewer separation distance and the number of viewers may be detected.

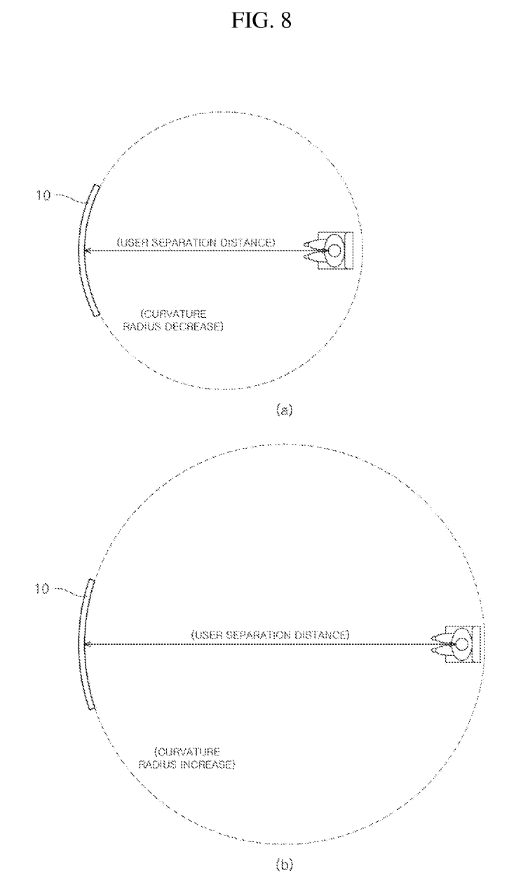

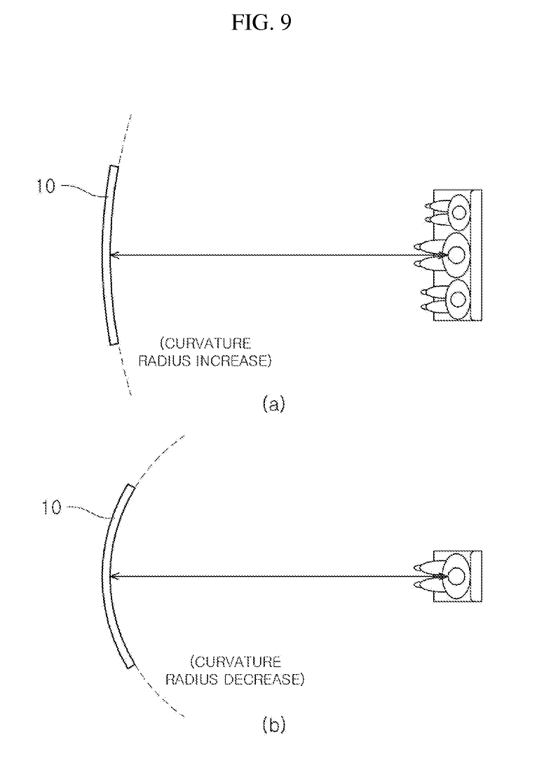

In the calculating of the flexible display optimal curvature value, an optimal curvature value of the flexible display corresponding to current viewer information is calculated by the optimal curvature calculation algorithm 41 provided in the display curvature control device 40 that receives the viewer information from the viewer information detection device 30. Here, in the calculating of the flexible display optimal curvature value, any one of an optimal curvature value of the flexible display 10 corresponding to the viewer separation distance, an optimal curvature value of the flexible display 10 corresponding to the number of viewers, and an optimal curvature value of the flexible display 10 corresponding to the viewer separation distance and the number of viewers may be calculated. In particular, in the calculating of the flexible display optimal curvature value according to an embodiment of the present invention, the optimal curvature value may be calculated in such a manner that a curvature radius of the flexible display 10 is increased along with an increase in the viewer separation distance as shown in FIGS. 8(a) and 8(b), and the optimal curvature value may be calculated in such a manner that the curvature radius of the flexible display 10 is increased along with an increase in the number of viewers as shown in FIGS. 9(a) and 9(b).

In the changing of the flexible display curvature, a current curvature of the flexible display 10 is changed by the curvature change device 20 that receives optimal curvature value information transmitted from the display curvature control device 40.

According to the system and method for controlling a curvature of a viewer adaptive type flexible display in order to increase an immersive feeling according to an embodiment of the present invention configured as above, a user may directly control the curvature of the flexible display 10 so that the curvature of the flexible display 10 may be changed according to the separation distance of the viewer positioned in front of the flexible display 10 and the number of viewers, or the separation distance of the viewer positioned in front of the flexible display 10 and the number of viewers may be detected in real time through the viewer separation distance detector 31 or the viewer number detector 32, an optimal curvature value corresponding to the separation distance of the viewer or the number of viewers may be calculated in real time by the display curvature control device 40 including the optimal curvature calculation algorithm 41, and the curvature of the flexible display 10 may be changed in real time to have an optimal curvature value by the curvature change device 20, and therefore it is possible to provide an optimal display environment that can be adapted to various viewing conditions, and thereby maximize an immersive feeling of the viewer. For example, in a case in which a viewer is playing a game alone, when positioned close to the flexible display 10, the viewer may receive a screen of the flexible display 10 which is close to a semicircle while a curvature radius of the flexible display 10 becomes remarkably small, and thereby maximize an immersive feeling of the viewer.

By the system and method for controlling a curvature of a viewer adaptive type flexible display in order to increase an immersive feeling according to an embodiment of the present invention, the curvature of the flexible display may be changed by direct control of a user, or the curvature of the flexible display may be changed in real time to have an optimal curvature value corresponding to a viewer separation distance or the number of viewers, and therefore it is possible to provide an optimal display environment that can be adapted to various viewing conditions, and thereby maximize an immersive feeling of the viewer.

As described above, the system and method for controlling a curvature of a viewer adaptive type flexible display in order to increase an immersive feeling according to an embodiment of the present invention have been shown by the aforementioned descriptions and drawings, but these are merely examples, and it will be well understood by those skilled in this art that various changes and modifications are possible within the scope and spirit of the present invention.

What is claimed is:

1. A system for controlling a curvature of a viewer adaptive type flexible display in order to increase an immersive feeling, the system comprising:
a flexible display that is made of a bendable flexible material whose curvature can be changed; and
a curvature change device that is installed in the flexible display and changes a current curvature of the flexible display,
wherein the curvature change device is controlled by any one selected from direct control by a user and automatic control by a display curvature control device.

2. The system of claim 1, further comprising:
a viewer information detection device that detects viewer information of a viewer positioned in front of the flexible display,
wherein the display curvature control device includes an optimal curvature calculation algorithm that receives the viewer information from the viewer information detection device and calculates an optimal curvature of the flexible display corresponding to the viewer information, and thereby generates optimal curvature value information corresponding to current viewer information and transmits the generated optimal curvature value information to the curvature change device.

3. The system of claim 1, wherein
the viewer information detection device is any one selected from a viewer separation distance detector for detecting a separation distance between a viewer positioned in front of the flexible display and the flexible display and a viewer number detector for detecting the number of viewers positioned in front of the flexible display, and
an optimal curvature calculation algorithm of the display curvature control device includes a separation distance adaptive type optimal curvature calculation algorithm for calculating an optimal curvature of the flexible display corresponding to the separation distance of the viewer, a viewer number adaptive type optimal curvature calculation algorithm for calculating the optimal curvature of the flexible display corresponding to the number of viewers, and a complex viewer information adaptive type optimal curvature calculation algorithm for calculating the optimal curvature of the flexible display corresponding to the separation distance of the viewer and the number of viewers.

4. The system of claim 1, wherein the curvature change device is any one selected from
an external curvature change device that includes a fixed block to which the flexible display is fixed and an actuator for the fixed block that changes a current curvature of the flexible display by moving the fixed block, and
an internal curvature change device that is disposed inside the flexible display to directly change a current curvature of a main substrate constituting the flexible display.

5. The system of claim 1, further comprising:
a viewer position detection device that detects a position of a viewer positioned in front of the flexible display;
a display rotation control device that includes a panning angle calculation algorithm for receiving a viewer position value from the viewer position detection device and calculating a panning angle of the flexible display corresponding to the viewer position value, and thereby generates a panning angle corresponding to a current viewer position; and
a display rotation device to which the flexible display is coupled, and that receives the panning angle from the display rotation control device and rotates the flexible display using the received panning angle.

6. The system of claim 1, further comprising:
a viewer position detection device that detects a position of a viewer positioned in front of the flexible display;
a display tilting control device that includes a tilting angle calculation algorithm for receiving a viewer position value from the viewer position detection device and calculating a tilting angle of the flexible display corresponding to the viewer position value, and thereby generates a tilting angle corresponding to a current viewer position; and
a display tilting device to which the flexible display is coupled, and that receives the tilting angle from the display tilting control device and rotates the flexible display using the received tilting angle.

7. A method for controlling a curvature of a viewer adaptive type flexible display in order to increase an immersive feeling, the method comprising:
detecting, by a viewer information detection device, viewer information of a viewer positioned in front of a flexible display that is made of a bendable flexible material whose curvature can be changed;
calculating, by an optimal curvature calculation algorithm provided in a display curvature control device that receives the viewer information from the viewer information detection device, an optimal curvature value of the flexible display corresponding to current viewer information; and
changing, by a curvature change device that receives the optimal curvature value transmitted from the display curvature control device, a current curvature of the flexible display.

8. The method of claim 7, wherein
the detecting of the viewer information includes detecting any one selected from a separation distance between the viewer positioned in front of the flexible display and the flexible display and the number of viewers positioned in front of the flexible display, as the viewer information, and
the calculating of the optimal curvature value includes calculating any one selected from the optimal curvature value of the flexible display corresponding to the separation distance of the viewer, the optimal curvature value of the flexible display corresponding to the number of viewers, and the optimal curvature value of the flexible display corresponding to the separation distance of the viewer and the number of viewers.

9. The method of claim 8, wherein the calculating of the optimal curvature value includes calculating the optimal curvature value in such a manner that a curvature radius of the flexible display is increased along with an increase in the separation distance of the viewer, and calculating the optimal curvature value in such a manner that the curvature radius of the flexible display is increased along with an increase in the number of viewers.
